(19) United States
(12) Patent Application Publication
(10) Pub. No.: US 2026/0247927 A1
(43) Pub. Date: Aug. 20, 2026

(54) Method for Increasing Pin Alignment Accuracy for a Power Semiconductor Module

(71) Applicant: Infineon Technologies AG, Neubiberg (DE)

(72) Inventors: Felix Spitzer, Dortmund (DE); Guido Strotmann, Anröchte (DE)

(21) Appl. No.: 19/058,677

(22) Filed: Feb. 20, 2025

(51) Int. Cl. H01L 21/66; H01L 21/48

(52) U.S. Cl. CPC H10P 74/238; H10W 70/093

(57) ABSTRACT

A method of increasing overall pin alignment accuracy for a power semiconductor module having a plurality of pins includes attaching a plurality of sleeves and one or more power semiconductor dies to a first side of a substrate; after the attaching, for each sleeve, measuring a sleeve positional offset between an actual sleeve position and a target sleeve position and calculating a pin insertion offset based on the sleeve positional offset; and for each pin, inserting the pin into a corresponding sleeve. The pin insertion offset is measured relative to a reference axis of the sleeve. The pin is inserted with the pin insertion offset calculated for the corresponding sleeve. Inserting the pin with the pin insertion offset reduces a deviation of a position of the inserted pin from a target position of the inserted pin.

### BACKGROUND

Demand for electronic modules for power applications, commonly referred to as power semiconductor modules, continues to increase rapidly across a wide range of industries, including automotive, consumer electronics, renewable energy, manufacturing, and medical, among many others. Developments in semiconductor materials such as silicon carbide (SiC) and gallium nitride (GaN) have enabled such power semiconductor modules to be manufactured with advantageous features such as smaller footprint, higher voltage and current capabilities, and faster switching speeds. Many applications have specific dimensional requirements and tolerances for features of the power semiconductor module that are used to assemble and/or interface the power semiconductor module with other components. A power semiconductor module that does not meet these requirements and tolerances may require manual handling during assembly of the power semiconductor module and a component or may even be deemed unusable for the given application.

Thus, there is a need for a solution that improves the alignment accuracy of features of a power semiconductor module that interface with another component.

### SUMMARY

According to an embodiment of method of increasing overall pin alignment accuracy for a power semiconductor module having a plurality of pins, the method comprises: attaching a plurality of sleeves and one or more power semiconductor dies to a first side of a substrate; after the attaching, for each sleeve: measuring a sleeve positional offset between an actual sleeve position and a target sleeve position, and calculating a pin insertion offset based on the sleeve positional offset, wherein the pin insertion offset is measured relative to a reference axis of the sleeve; and for each pin, inserting the pin into a corresponding sleeve, wherein the pin is inserted with the pin insertion offset calculated for the corresponding sleeve, wherein inserting the pin with the pin insertion offset reduces a deviation of a position of the inserted pin from a target position of the inserted pin.

According to an embodiment of method for forming a power semiconductor module, the method comprises: attaching a plurality of sleeves and one or more power semiconductor dies to a first side of a substrate; after the attaching, for each sleeve: measuring a sleeve positional offset between an actual sleeve position and a target sleeve position, and calculating a pin insertion offset based on the sleeve positional offset, wherein the pin insertion offset is measured relative to a reference axis of the sleeve; inserting a first pin into a first sleeve having a first pin insertion offset, wherein the first pin is inserted with the first pin insertion offset, and after inserting the first pin into the first sleeve, inserting a second pin into a second sleeve having a second pin insertion offset, wherein the second pin insertion offset is different than the first pin insertion offset, and wherein the second pin is inserted with the second pin insertion offset.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a method for attaching a plurality of sleeves and one or more power semiconductor dies to a substrate, according to an embodiment.

FIGS. 2A and 2B illustrate methods for measuring a sleeve positional offset between an actual sleeve position and a target sleeve position, according to embodiments.

FIGS. 3A and 3B illustrate methods for calculating a pin insertion offset based on the sleeve positional offset, according to embodiments.

FIGS. 4A and 4B illustrate methods for inserting pins into corresponding sleeves with pin insertion offsets, according to embodiments.

FIGS. 5A and 5B Illustrate methods for adjusting a pin insertion position of a substrate and inserting a pin into a corresponding sleeve, according to embodiments.

FIGS. 6A and 6B Illustrate methods for adjusting a pin insertion position of a placement tool and inserting a pin into a corresponding sleeve, according to embodiments.

FIG. 7 illustrates an assembly of a power semiconductor module and a component, according to an embodiment.

### DETAILED DESCRIPTION

Described herein are methods for forming a power semiconductor module that includes a plurality of pins. The pins are configured to interface with an external component of an application (e.g., a PCB) and provide an electrical interface for the power semiconductor module. Misalignment of the pins may increase the complexity of the process of assembling the power semiconductor module with a component, as misaligned pins may not properly mate with corresponding openings of the component and may require manual handling to form a proper interface. In some instances, misalignment of the pins exceeding certain tolerances of the application may render the power semiconductor module unusable for the application.

The pins are inserted into sleeves attached to a substrate of the power semiconductor module. Like the pins, the sleeves have target positions, and any deviation of a sleeve position from its target position may result in a corresponding misalignment of the pin from its target position. The resulting misalignment may take the form of a linear, horizontal displacement of the sleeve from its target position, herein termed as lateral displacement/offset. The resulting misalignment may in addition, or instead, also take the form of an angular displacement, where the target position is typically vertical and the actual sleeve is tilted, such that it lies angled with respect to the vertical direction. According to embodiments described herein, the misalignment of the sleeves from their target linear and/or angular positions is measured and a pin insertion offset that compensates for this misalignment is calculated for each sleeve. The pins are then inserted into the sleeves with the corresponding pin insertion offset of each sleeve. Measuring the misalignment of the sleeves, calculating a pin insertion offset for each sleeve based on the sleeve misalignment, and inserting each pin into a sleeve with the corresponding pin insertion offset may reduce a deviation of each inserted pin from its target position and may increase the likelihood that the pins will properly interface with a component when assembling the power semiconductor module with the component. In some instances, reducing the deviation of each inserted pin from its target position may enable the assembly of the power semiconductor module and the component to be completed with an automated process, potentially providing a more cost-effective manufacturing process.

Described next, with reference to the figures, are exemplary embodiments of a method for increasing overall pin alignment accuracy when forming a power semiconductor module.

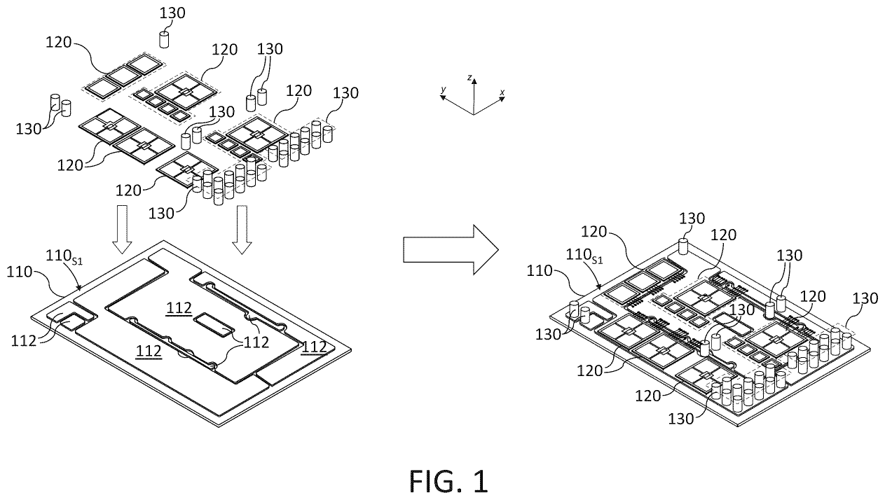

FIG. 1 illustrates a method for attaching a plurality of sleeves 130 and one or more power semiconductor dies 120 to a substrate 110, according to an embodiment. Examples of the substrate 110 include a DCB (direct copper bonded) or AMB (active metal brazed) substrate, printed circuit board (PCB), lead frame, or other substrate, e.g., insulated metal substrate (IMS), etc. The substrate 110 may include one or more insulating layers and/or metallization layers. An insulating layer may include a ceramic, a polymer such as polyimide, etc. A metallization layer may include copper, aluminum, an alloy, etc., and may include one or more traces and/or contact pads. The substrate 110 of FIG. 1 includes a metallization layer 112 on a first side 110_{S1} of the substrate 110.

Each power semiconductor die 120 may include one or more devices, e.g., one or more transistors, diodes, resistors, capacitors, and/or other types of active or passive devices. One or more of the power semiconductor dies 120 may be a vertical power semiconductor die (e.g., a vertical power transistor die). For a vertical power transistor die, the primary current flow path is between the front and back sides of the power semiconductor die 120 (along the z direction in FIG. 1). In one embodiment, one or more power semiconductor dies 120 are SiC transistor dies such as SiC power MOSFET (metal-oxide-semiconductor field-effect transistor) dies. One or more of the power semiconductor dies 120 may be a Si power MOSFET die, HEMT (high-electron mobility transistor) die, IGBT (insulated-gate bipolar transistor) die, JFET (junction filed-effect transistor) die, etc. In examples where more than one power semiconductor die 120 is attached to the substrate 110, the power semiconductor dies 120 may all be of a similar or identical design (e.g., device type, structure, materials, dimensions, etc.), or some or each of the power semiconductor dies 120 may have different designs. Various arrangements of designs of power semiconductor dies 120 on the substrate 110 are contemplated. For example, one or more power semiconductor dies 120 may be arranged on the substrate 110 to form all or part of a circuit of a power semiconductor module, such as a DC/AC inverter, a DC/DC converter, an AC/DC converter, a DC/AC converter, an AC/AC converter, a multi-phase inverter, an H-bridge, motor driver, etc. In some examples, a circuit that includes one or more of the power semiconductor dies 120 is a half-bridge or full-bridge circuit.

The sleeves 130 may be formed of a metal or metal alloy such as copper, aluminum, etc. In some examples, one or more sleeves 130 further include an electrically insulative cover or coating.

The sleeves 130 and the power semiconductor die(s) 120 are attached to the first side 110_{S1} of the substrate 110. In the example of FIG. 1, the sleeves 130 and the power semiconductor dies 120 are attached to the metallization layer 112, although one or more of the sleeves 130 and/or the semiconductor dies 120 may be attached to a different metallization layer or other parts of the substrate 110. The sleeves 130 may be attached to the substrate 110 (e.g., the metallization 112 layer or another metallization layer) by soldering (e.g., using soft solder, using solder paste), diffusion soldering, adhering, gluing, laser welding, ultrasonic welding, etc. The power semiconductor dies 120 may be attached to the substrate 110 (e.g., the metallization layer 112 or another metallization layer) by soldering, diffusion soldering, brazing, adhering, etc.

Each sleeve 130 is configured to receive a pin (not illustrated in FIG. 1) and may electrically couple the pin to one or more power semiconductor dies 120 (e.g., through the metallization layer 112). As will be discussed further, the pins provide an electrical interface for the power semiconductor module. Deviation in the placement of the sleeves 130 from their target positions on the substrate 110, e.g., due to manufacturing variability, may result in a corresponding deviation of the positions of the pins inserted into the sleeves 130 from their respective target positions. If such deviations of the pin positions from their target positions exceed the tolerances of a given application (e.g., an application requiring the pins to be inserted into holes of a printed circuit board), the power semiconductor module may require manual handling for incorporation into the target application or may even be unusable for the target application.

The remainder of this disclosure describes embodiments of a method for reducing pin placement inaccuracy related to variability in the placement of the sleeves 130 on the substrate 110.

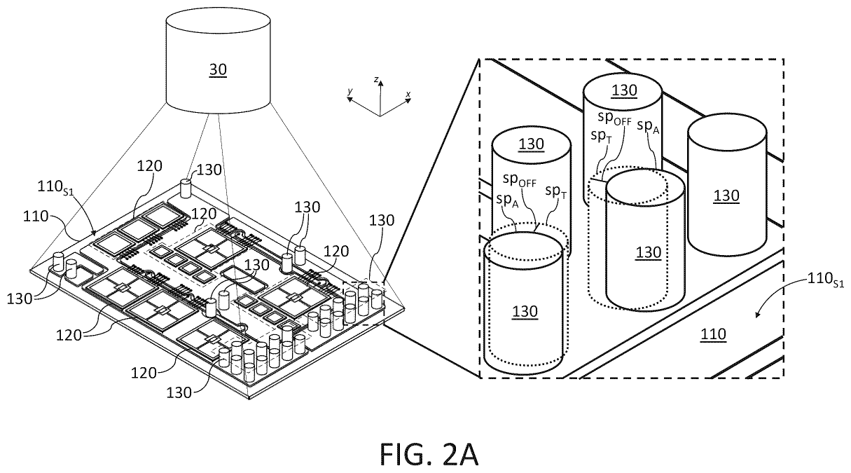

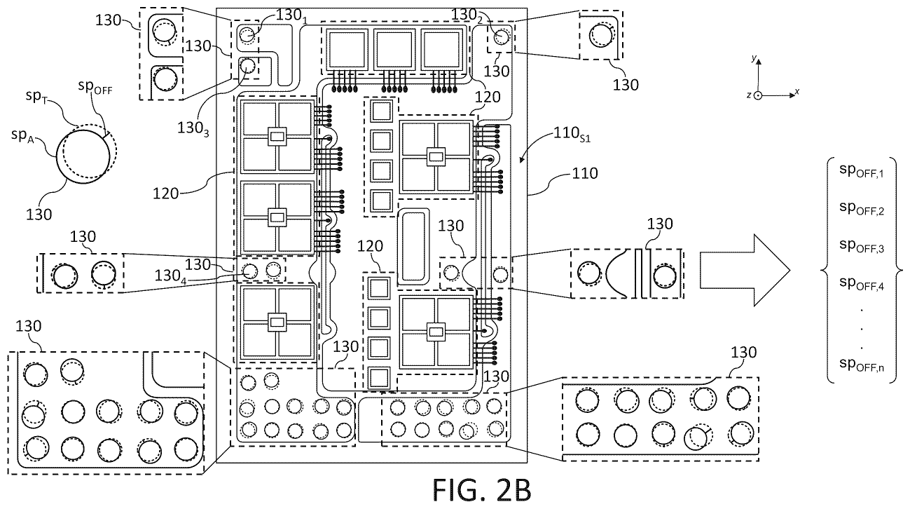

FIGS. 2A and 2B illustrate methods for measuring a sleeve positional offset sp_{OFF} between an actual sleeve position sp_{A} and a target sleeve position sp_{T}, according to embodiments.

After attaching the sleeves 130 to the substrate 110 as illustrated in FIG. 1, the sleeve positional offset sp_{OFF} between the actual sleeve position sp_{A} and the target sleeve position sp_{T} is measured for each of the sleeves 130. Measuring the sleeve positional offsets sp_{OFF} between the actual sleeve positions sp_{A} and a target sleeve positions sp_{T} may include imaging (e.g., x-ray imaging, optical imaging, scanning acoustic microscopy, computer tomography, etc.) the plurality of sleeves 130 attached to the substrate 110 using an imaging device 30, as illustrated in FIG. 2A.

FIG. 2B illustrates a top-down plan view of the substrate 110, the power semiconductor dies 120, and the sleeves 130. The target sleeve position sp_{T}, actual sleeve position sp_{A}, and sleeve positional offset sp_{OFF} in the x and y directions is shown for each of the sleeves 130 attached to the substrate 110. That is, each sleeve 130ₙ of the plurality of n sleeves 130 (sleeve 130₁, sleeve 130₂, sleeve 130₃, sleeve 130₄, . . . sleeve 130ₙ) has a corresponding sleeve positional offset sp_{OFF,n} (sp_{OFF,1}, sp_{OFF,2}, sp_{OFF,3}, sp_{OFF,4}, . . . sp_{OFF,n}) that is measured and may be collected, stored, reported, exported, etc.

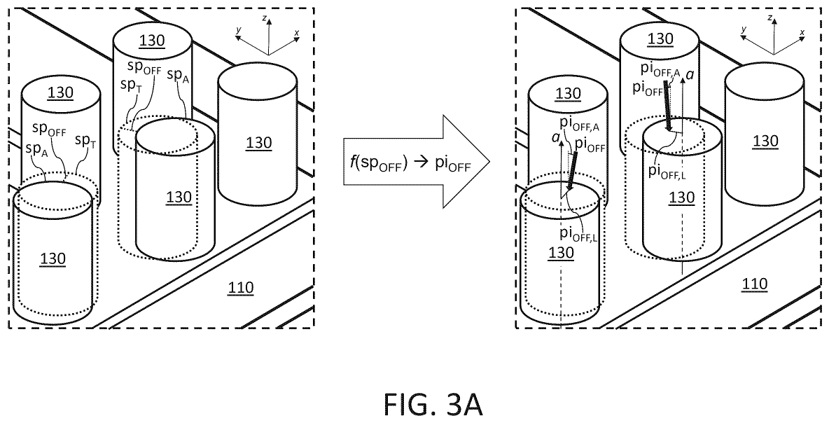

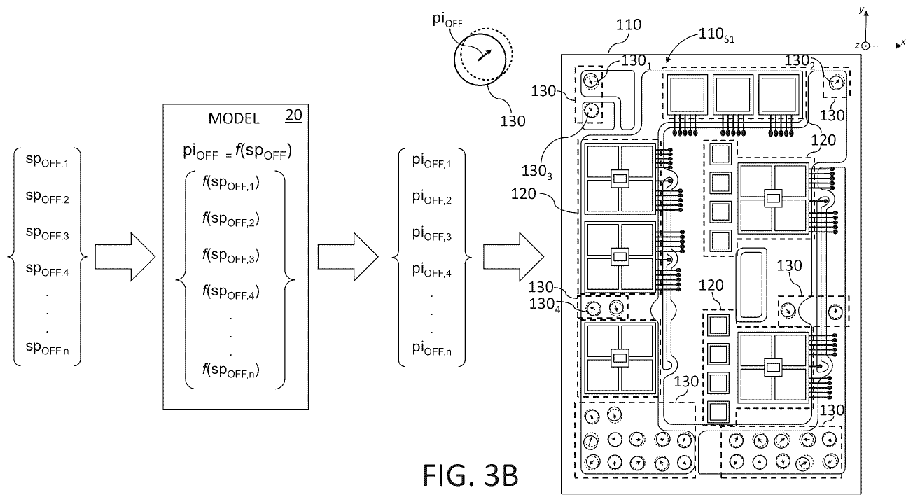

FIGS. 3A and 3B illustrate methods for calculating a pin insertion offset pi_{OFF} based on the sleeve positional offset sp_{OFF}, according to embodiments. That is, the pin insertion offset pi_{OFF} of a respective sleeve 130 is a function of the sleeve positional offset sp_{OFF} of the respective sleeve 130. As illustrated in FIG. 3A, the pin insertion offset pi_{OFF} of a respective sleeve 130 may include a lateral offset pi_{OFF,L} and/or an angular offset pi_{OFF,A} that are each measured relative to a reference axis a of the respective (actual) sleeve 130.

FIG. 3B illustrates calculating a corresponding pin insertion offset pi_{OFF} for each sleeve 130ₙ of the plurality of n sleeves 130 attached to the substrate 110. Specifically, FIG. 3B illustrates calculating the pin insertion offset pi_{OFF} for each sleeve 130 based on the sleeve positional offset sp_{OFF} of the sleeve by inputting the sleeve positional offset sp_{OFF} into a model 20. The model 20 may include a geometry of the pins to be inserted into the sleeves 130 (e.g., length, width), an elasticity and/or plasticity of the pins to be inserted into the sleeves 130, a geometry of the sleeves 130 (e.g., height, diameter), an elasticity of the sleeves 130, and/or a plasticity of the sleeves 130, among other factors. The model 20 may be performed by a computer or other system that outputs or exports the calculated pin insertion offsets pi_{OFF}, e.g., to another computer, system, tool, machine, etc.

As illustrated in FIG. 3B, the sleeve positional offsets sp_{OFF} for each of the n sleeves 130 measured according to the steps of FIGS. 2A and 2B are input into the model 20. The model 20 outputs corresponding pin insertion offsets pi_{OFF} for each of the n sleeves 130 (pi_{OFF,1}, pi_{OFF,2}, pi_{OFF,3}, pi_{OFF,4}, . . . pi_{OFF,n}). Like the sleeve positional offsets sp_{OFF}, the pin insertion offsets pi_{OFF} of the pins 130 may be collected, stored, reported, exported, etc.

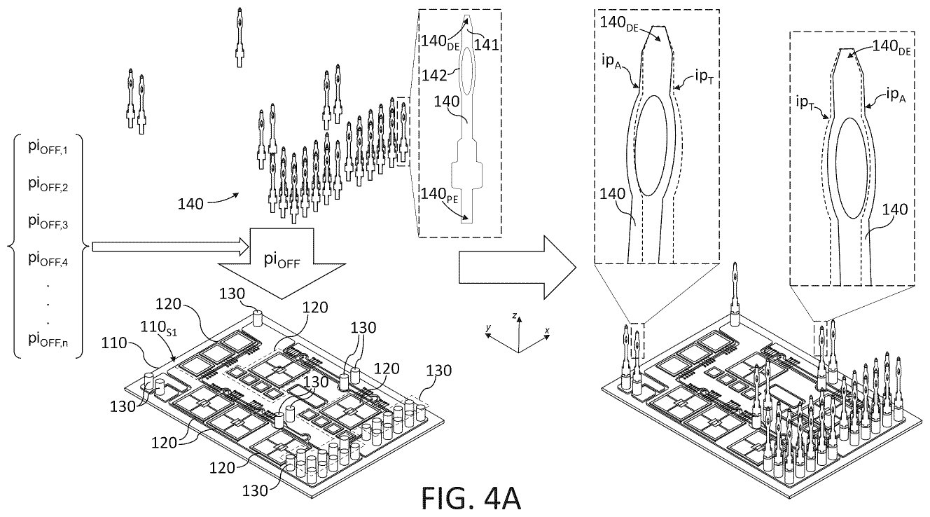

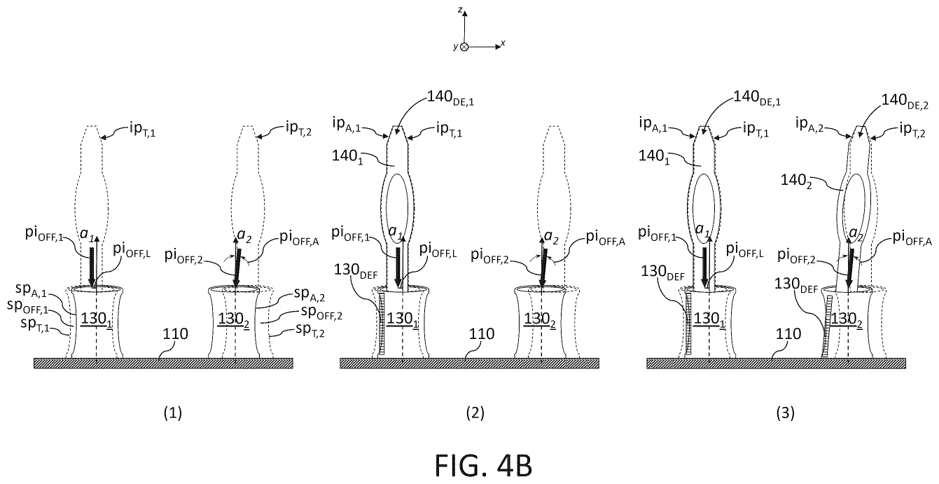

FIGS. 4A and 4B illustrate methods for inserting pins 140 into corresponding sleeves 130 with pin insertion offsets pi_{OFF}, according to embodiments. The pins 140 may be formed of copper, aluminum, an alloy (e.g., a nickel tin alloy), or another electrically conductive material. As noted previously, the pins 140 provide an electrical interface for the power semiconductor module, with each pin 140 configured to interface with a component (e.g., a PCB) of the application into which the power semiconductor module will be integrated. In this example, a distal end 140_{DE} of each pin 140 is a press-fit end that includes a tip part 141 and a deformable part 142 adjoining the tip part 141. For such a configuration, the tip part 141 of the pin 140 may be inserted through a hole of a PCB or other type of substrate (not shown in FIGS. 4A and 4B) and the deformable part 142 may plastically and/or elastically deform when pressed against the walls of the hole, thus securing the pin 140 to the substrate. Other configurations of the pins 140 and means of interfacing the pins 140 with a component are contemplated. For example, the distal ends 140_{DE} of the pins 140 may be soldered to a component such as a PCB.

A proximal end 140_{PE} of each pin 140 is inserted into a corresponding sleeve 130 attached to the substrate 110. Each pin 140 is inserted with the pin insertion offset pi_{OFF} that was calculated for the corresponding sleeve 130 in the steps illustrated in FIGS. 3A and 3B. The proximal end 140_{PE} of a respective pin 140 may be press fit into the corresponding sleeve 130. In some examples, the proximal end 140_{PE} of a given pin 140 is soldered to the corresponding sleeve 130.

As illustrated in FIG. 4A, inserting each pin 140 with the pin insertion offset pi_{OFF} of the corresponding sleeve 130 may reduce a deviation of a position ip_{A} of the inserted pin 140 from a target position ip_{T} of the inserted pin 140. In this example, the position ip_{A} of each inserted pin 140 is a position of the distal end 140_{DE} of the inserted pin 140, and the target position ip_{T} of each inserted pin 140 is a target position of the distal end 140_{DE} of the inserted pin 140.

Step (1) of FIG. 4B illustrates a first sleeve 130₁ and a second sleeve 130₂ that have been attached to the substrate 110 (e.g., using the steps of FIG. 1). The first sleeve 130₁ has a first sleeve positional offset sp_{OFF,1} between a first actual sleeve position sp_{A,1} and a first target sleeve position sp_{T,1} of the first sleeve 130₁. The second sleeve 130₂ has a second sleeve positional offset sp_{OFF,2} between a second actual sleeve position sp_{A,2} and a second target sleeve position sp_{T,2} of the second sleeve 130₂. The first sleeve positional offset sp_{OFF,1} and the second sleeve positional offset sp_{OFF,2} of the first sleeve 130₁ and the second sleeve 130₂, respectively, may be measured, collected, exported, etc. using the steps of FIGS. 2A and 2B. Step (1) of FIG. 4B identifies a target position ip_{T,1} and ip_{T,2} for the pins 140 that are to be inserted into each of the first sleeve 130₁ and the second sleeve 130₂, respectively. The target positions ip_{T,1} and ip_{T,2} are based on the target positions sp_{T,1} and sp_{T,2} of the first sleeve 130₁ and the second sleeve 130₂, respectively, and may correspond to target positions of the pins 140 for a given application of the power semiconductor module (e.g., positions of holes in a PCB). In this example, the target positions ip_{T,1} and ip_{T,2} are target positions for a distal end 140_{DE} of the respective pins 140.

A first pin insertion offset pi_{OFF,1} and a second pin insertion offset pi_{OFF,2} are calculated for the first sleeve 130₁ and the second sleeve 130₂, respectively. The first pin insertion offset pi_{OFF,1} and the second pin insertion offset pi_{OFF,2} may be calculated from the first sleeve positional offset sp_{OFF,1} and the second sleeve positional offset sp_{OFF,2}, respectively, using the steps of FIGS. 3A and 3B. In this example, the second pin insertion offset pi_{OFF,2} of the second sleeve 130₂ is different from the fist pin insertion offset pi_{OFF,1} of the first sleeve 130₁. The first pin insertion offset pi_{OFF,1} is measured relative to a reference axis a₁ of the first sleeve 130₁ and has a lateral offset pi_{OFF,L}. The second pin insertion offset pi_{OFF,2} is measured relative to a reference axis a₂ of the second sleeve 130₂ and has an angular offset pi_{OFF,A}. This is only one example, however, and the first pin insertion offset pi_{OFF,1} and/or the second pin insertion offset pi_{OFF,2} may include any combination of lateral offset pi_{OFF,L} and/or angular offset pi_{OFF,A} based on the measured sleeve positional offset sp_{OFF,1} and sp_{OFF,2}, respectively.

Step (2) of FIG. 4B illustrates inserting a first pin 140₁ into the first sleeve 130₁. The first pin 140₁ is inserted with the first pin insertion offset pi_{OFF,1}. Step (3) of FIG. 4B illustrates inserting a second pin 140₂ into the second sleeve 130₂ after inserting the first pin 140₁ into the first sleeve 130₁. The second pin 140₂ is inserted with the second pin insertion offset pi_{OFF,2}. As a result of inserting the first pin 140₁ into the first sleeve 130₁ with the first pin insertion offset pi_{OFF,1}, a deviation of the position ip_{A,1} of the inserted pin 140₁ from the target position ip_{T,1} may be reduced. Likewise, as a result of inserting the second pin 140₂ into the second sleeve 130₂ with the second pin insertion offset pi_{OFF,2}, a deviation of the position ip_{A,2} of the inserted pin 140₂ from the target position ip_{T,2} may be reduced. The steps of FIG. 4B may be repeated for the remaining pins 140 of FIG. 4A. That is, each of the remaining pins 140 may be inserted with the corresponding pin insertion offset pi_{OFF} into a corresponding sleeve 130, thus increasing the overall alignment accuracy of the pins 140 (e.g., the positions ip_{A} of the distal ends 140_{DE} of the pins 140 relative to their respective target positions ip_{T}) and potentially increasing the likelihood that the pins 140 will meet the tolerance requirements of a given application for the power semiconductor module.

As illustrated in steps (2) and (3) of FIG. 4B, each of the first sleeve 130₁ and the second sleeve 130₂ experiences a deformation 130_{DEF} upon insertion of the respective pins 140₁ and 140₂. The deformation 130_{DEF} of the first sleeve 130₁, the second sleeve 130₂, and other sleeves 130 attached to the substrate 110 (e.g., those sleeves 130 having a non-zero pin insertion offset pi_{OFF}) may be an effect of deliberately utilizing pins 140 with a hardness that is greater than a hardness of the sleeves 130. In some instances, a majority of the deformation 130_{DEF} of a sleeve 130 that occurs when inserting the corresponding pin 140 into the sleeve 130 is plastic deformation. Utilizing sleeves 130 that deform (e.g., deform plastically) upon insertion of a corresponding pin 140 may facilitate the insertion of the pins 140 with the calculated pin insertion offsets pi_{OFF} and may ensure that the pin 140 remains securely inserted in the corresponding sleeve 130. However, any elastic sleeve deformation that takes place upon pin insertion must also be recognized and accounted for in calculating the correct pin insertion offset pi_{OFF}.

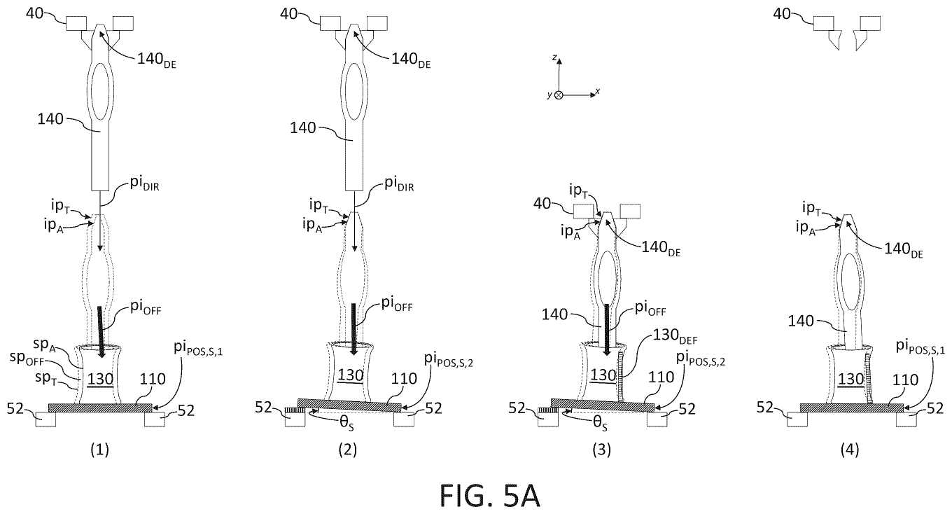

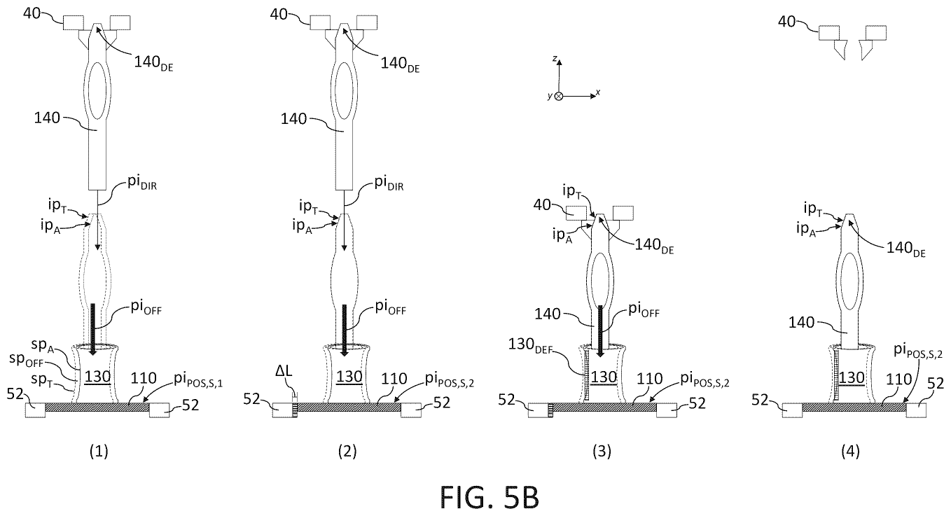

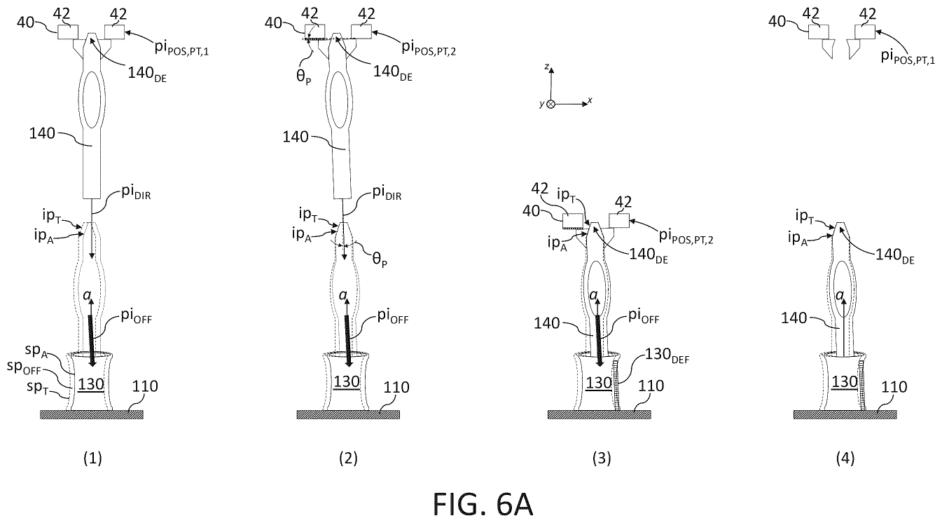

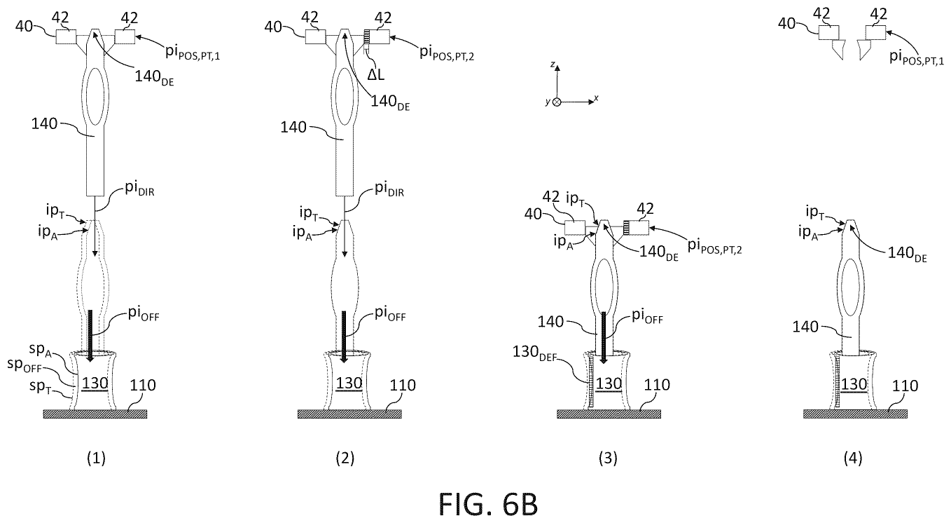

FIGS. 5A-6B illustrate several embodiments methods for inserting a pin 140 into a corresponding sleeve 130 with the pin insertion offset pi_{OFF} calculated for the corresponding sleeve 130 with a placement tool 40. The placement tool 40 is a machine that includes a mechanism such as an arm to pick up each pin 140 and insert the pin 140 into a corresponding sleeve 130. In some examples, the placement tool 40 includes a means for adjusting a pin insertion position pi_{POS} of the placement tool 40 and/or the substrate 110, e.g., a piezoelectric actuator. The placement tool 40 may also include a means for referencing the actual sleeve positions sp_{A}, pin insertion offsets pi_{OFF}, and/or other aspects of the sleeves 130, the substrate 110, etc. For example, the placement tool 40 may include a database or library that stores the pin insertion offsets pi_{OFF} for a given set of pins 140. Alternatively, the placement tool 40 may be interfaced with a computer or other system that stores and outputs/exports the pin insertion offsets pi_{OFF} to the placement tool 40. In some instances, the placement tool 40 may be interfaced with a computer or other system that performs the model 20 illustrated in FIG. 3B and outputs/exports the calculated pin insertion offsets pi_{OFF} to the placement tool 40.

Any of the steps of FIGS. 5A-6B may be combined for the insertion of a single pin 140 and/or multiple pins 140. It should be noted that while FIGS. 5A-6B illustrate sleeve positional offsets sp_{OFF}, pin insertion offsets pi_{OFF}, and adjustments to pin insertion positions pi_{POS} in the x and z directions, each of these may also include components in the y direction. Additionally, it should be noted that the steps illustrated FIGS. 5A-6B are focused on the geometrical aspects of the pin insertion offsets pi_{OFF} and the corresponding adjustments made to the pin insertion positions pi_{POS}. However, as mentioned previously, the pin insertion offsets pi_{OFF} are not solely determined by geometry and may also factor in material properties, geometries, etc. of the sleeves 130 and/or the pins 140. Thus, it should be understood that the pin insertion offsets pi_{OFF} of FIGS. 5A-6B may not be entirely representative of all the factors that determine the pin insertion offset pi_{OFF} for a given sleeve 130. However, the application of a pin insertion offset pi_{OFF} to reduce a deviation of a position ip_{A} of an inserted pin 140 from a target position ip_{T} of the inserted pin 140 as illustrated in FIGS. 5A-6B is the same regardless of whether the pin insertion offset pi_{OFF} includes non-geometric factors.

FIGS. 5A and 5B Illustrate methods for adjusting a pin insertion position pi_{POS,S} of the substrate 110 and inserting a pin 140 into a corresponding sleeve 130, according to embodiments. In the examples of FIGS. 5A and 5B, inserting the pin 140 with the pin insertion offset pi_{OFF} calculated for the corresponding sleeve 130 includes adjusting the pin insertion position pi_{POS,S} of the substrate 110 to account for the pin insertion offset pi_{OFF} before inserting the pin 140 into the corresponding sleeve 130 with the placement tool 40. The pin insertion position pi_{POS,S} of the substrate 110 is adjusted in the examples of FIGS. 5A and 5B using a piezoelectric actuator 52 that is adjacent to the substrate 110, although other means of adjusting the pin insertion position pi_{POS,S} of the substrate 110 are contemplated. The piezoelectric actuator 52 may be part of a platform, stage, or other feature that is configured to support the substrate 110. In some examples, the placement tool 40 itself includes such a platform, stage, or other feature.

Step (1) of each of FIGS. 5A and 5B illustrates a sleeve 130 that has been attached to the substrate 110 (e.g., using the steps of FIG. 1) and a pin 140 held by the placement tool 40. In each example, the substrate 110 is in a first pin insertion position pi_{POS,S,1}. The sleeve 130 has a sleeve positional offset sp_{OFF} between an actual sleeve position sp_{A} and a target sleeve position sp_{T} of the sleeve 130. The sleeve positional offset sp_{OFF} may be measured, collected, exported, etc. using the steps of FIGS. 2A and 2B. A pin insertion offset pi_{OFF} of the sleeve 130 is also illustrated in each of FIGS. 5A and 5B. The pin insertion offset pi_{OFF} may be calculated from the sleeve positional offset sp_{OFF} using the steps of FIG. 3A 3B.

Step (1) of each of FIGS. 5A and 5B identifies a target position ip_{T} for the pin 140. The target position ip_{T} is based on the target position sp_{T} of the sleeve 130 and may correspond to a target position of the pin 140 for a given application of the power semiconductor module (e.g., positions of holes on a PCB). In these examples, the target position ip_{T} is a target position for the distal end 140_{DE} of the pin 140.

Step (1) of each of FIGS. 5A and 5B also identifies a position ip_{A} and a pin insertion direction pi_{DIR} for the pin 140. The position ip_{A} corresponds to where the pin 140 would be placed with the pin insertion direction pi_{DIR} and with the substrate 110 in the first pin insertion position pi_{POS,S,1} of step (1). The first pin insertion position pi_{POS,S,1} of the substrate 110 thus corresponds to the default placement of the pin 140 into a corresponding sleeve 130 with the measured sleeve positional offset sp_{OFF}, and the deviation of the position ip_{A} from the target position ip_{T} illustrated in step (1) represents the misalignment of the pin 140 if it were to be inserted into the sleeve 130 without the pin insertion offset pi_{OFF}.

Step (2) of each of FIGS. 5A and 5B illustrates adjusting the pin insertion position pi_{POS,S} of the substrate 110 to a second pin insertion position pi_{POS,S,2} to account for the pin insertion offset pi_{OFF} of the sleeve 130. In step (2) of FIG. 5A, adjusting the pin insertion position pi_{POS,S} of the substrate 110 includes tilting the substrate 110 at an angle θ_{S} relative to the pin insertion direction pi_{DIR} of the pin 140. In step (2) of FIG. 5B, adjusting the pin insertion position pi_{POS,S} of the substrate 110 includes moving the substrate 110 in a lateral direction x and/or y by ΔL relative to the pin insertion direction pi_{DIR} of the pin 140. In both instances, tilting/moving the substrate 110 in step (2) may be accomplished by actuating the piezoelectric actuator 52 adjacent to the substrate 110. Step (2) may also include a combination of an angular adjustment, as illustrated in FIG. 5A, and a lateral adjustment, as illustrated in FIG. 5B.

As illustrated in step (2) of each of FIGS. 5A and 5B, adjusting the pin insertion position pi_{POS,S} of the substrate 110 to account for the pin insertion offset pi_{OFF} of the sleeve 130 shifts the position ip_{A} closer to the target position ip_{T}, representing the effect of applying the pin insertion offset pi_{OFF} on the placement of the pin 140. This effect is also represented with the alignment of the pin insertion offset pi_{OFF} with the pin insertion direction pi_{DIR} in the z direction, although, as noted previously, the pin insertion offset pi_{OFF} of FIGS. 5A and 5B only represents the geometric aspects of the pin insertion offset pi_{OFF}.

Step (3) of each of FIGS. 5A and 5B illustrates inserting the pin 140 into the sleeve 130 with the pin insertion tool 40. The substrate 110 is maintained at the second pin insertion position pi_{POS,S,2} when the pin 140 is inserted into the sleeve 130 so that the pin is inserted with the pin insertion offset pi_{OFF}. As a result, the position ip_{A} of the inserted pin 140 is more closely aligned with the target position ip_{T}.

Step (4) of each of FIGS. 5A and 5B illustrates releasing the inserted pin 140 from the pin insertion tool 40. The substrate 110 may be returned to the first pin insertion position pi_{POS,S,1}, to prepare for the insertion of additional pins 140. Steps (1)-(3) of FIGS. 5A and/or 5B may be repeated for the remaining pins 140. That is, each of the remaining pins 140 may be inserted with the corresponding pin insertion offset pi_{OFF} into a corresponding sleeve 130 using steps (1)-(3), thus increasing the overall alignment accuracy of the pins 140 (e.g., the positions ip_{A} of the distal ends 140_{DE} of the pins 140 relative to their respective target positions ip_{T}) and potentially increasing the likelihood that pins 140 will meet the tolerance requirements of a given application for the power semiconductor module.

FIGS. 6A and 6B Illustrate methods for adjusting a pin insertion position pi_{POS,PT} of the placement tool 40 and inserting a pin 140 into a corresponding sleeve 130, according to embodiments. In the examples of FIGS. 6A and 6B, inserting the pin 140 with the pin insertion offset pi_{OFF} calculated for the corresponding sleeve 130 includes adjusting the pin insertion position pi_{POS,PT} of the placement tool 40 to account for the pin insertion offset pi_{OFF} before inserting the pin 140 into the corresponding sleeve 130 with the placement tool 40. The pin insertion position pi_{POS,PT} of the placement tool 40 is adjusted in the examples of FIGS. 6A and 6B using a piezoelectric actuator 42 that is adjacent to the distal end 140_{DE} of the pin 140, although other means of adjusting the pin insertion position pi_{POS,PT} of the placement tool 40 are contemplated. The piezoelectric actuator 42 may be part of an arm of the placement tool 40.

Like step (1) of FIGS. 5A and 5B, step (1) of each of FIGS. 6A and 6B illustrates a sleeve 130 that has been attached to the substrate 110 (e.g., using the steps of FIG. 1) and a pin 140 held by the placement tool 40. In each example, the placement tool 40 is in a first pin insertion position pi_{POS,PT,1}. The sleeve 130 has a sleeve positional offset sp_{OFF} between an actual sleeve position sp_{A} and a target sleeve position sp_{T} of the sleeve 130. The sleeve positional offset sp_{OFF} may be measured, collected, exported, etc. using the steps of FIGS. 2A and 2B. A pin insertion offset pi_{OFF} of the sleeve 130 is also illustrated in each of FIGS. 6A and 6B. The pin insertion offset pi_{OFF} may be calculated from the sleeve positional offset sp_{OFF} using the steps of FIG. 3A 3B.

Step (1) of each of FIGS. 6A and 6B identifies a target position ip_{T} for the pin 140. The target position ip_{T} is based on the target position sp_{T} of the sleeve 130 and may correspond to a target position of the pin 140 for a given application of the power semiconductor module (e.g., positions of holes on a PCB). In these examples, the target position ip_{T} is a target position for the distal end 140_{DE} of the pin 140.

Step (1) of each of FIGS. 6A and 6B also identifies a position ip_{A} and a pin insertion direction pi_{DIR} for the pin 140. The position ip_{A} corresponds to where the pin 140 would be placed with the pin insertion direction pi_{DIR} and with the placement tool 40 in the first pin insertion position pi_{POS,PT,1} of step (1). The first pin insertion position pi_{POS,PT,1} of the placement tool 40 thus corresponds to the default placement of the pin 140 into a corresponding sleeve 130 with the measured sleeve positional offset sp_{OFF}, and the deviation of the position ip_{A} from the target position ip_{T} illustrated in step (1) represents the misalignment of the pin 140 if it were to be inserted into the sleeve 130 without the pin insertion offset pi_{OFF}.

Step (2) of each of FIGS. 6A and 6B illustrates adjusting the pin insertion position pi_{POS,PT} of the placement tool 40 to a second pin insertion position pi_{POS,PT,2} to account for the pin insertion offset pi_{OFF} of the sleeve 130. In step (2) of FIG. 6A, adjusting the pin insertion position pi_{POS,PT} of the placement tool includes tilting the pin at an angle θ_{P} relative to the reference axis a of the sleeve. In step (2) of FIG. 6B, adjusting the pin insertion position pi_{POS,PT} of the placement tool 40 includes moving the pin 140 in a lateral direction x and/or y by DL relative to the reference axis a of the sleeve 130. In both instances, tilting/moving the placement tool 40 in step (2) may be accomplished by actuating the piezoelectric actuator 42 adjacent to the distal end 140_{DE} of the pin 140. Step (2) may also include a combination of an angular adjustment, as illustrated in FIG. 6A, and a lateral adjustment, as illustrated in FIG. 6B.

As illustrated in step (2) of each of FIGS. 6A and 6B, adjusting the pin insertion position pi_{POS,S} of the substrate 110 to account for the pin insertion offset pi_{OFF} of the sleeve 130 shifts the position ip_{A} closer to the target position ip_{T}, representing the effect of applying the pin insertion offset pi_{OFF} on the placement of the pin 140. This effect is also represented with the alignment of the pin insertion direction pi_{DIR} with the pin insertion offset pi_{OFF} in the z direction, although, as noted previously, the pin insertion offset pi_{OFF} of FIGS. 6A and 6B only represents the geometric aspects of the pin insertion offset pi_{OFF}.

Step (3) of each of FIGS. 6A and 6B illustrates inserting the pin 140 into the sleeve 130 with the pin insertion tool 40. The placement tool 40 is maintained at the second pin insertion position pi_{POS,PT,2} when the pin 140 is inserted into the sleeve 130 so that the pin is inserted with the pin insertion offset pi_{OFF}. As a result, the position ip_{A} of the inserted pin 140 is more closely aligned with the target position ip_{T}.

Step (4) of each of FIGS. 6A and 6B illustrates releasing the inserted pin 140 from the placement tool 40. The placement tool 40 may be returned to the first pin insertion position pi_{POS,PT,1}, to prepare for the insertion of additional pins 140. Steps (1)-(3) of FIGS. 6A and/or 6B may be repeated for the remaining pins 140. That is, each of the remaining pins 140 may be inserted with the corresponding pin insertion offset pi_{OFF} into a corresponding sleeve 130 using steps (1)-(3), thus increasing the overall alignment accuracy of the pins 140 (e.g., the positions ip_{A} of the distal ends 140_{DE} of the pins 140 relative to their respective target positions ip_{T}) and potentially increasing the likelihood that the pins 140 will meet the tolerance requirements of a given application for the power semiconductor module.

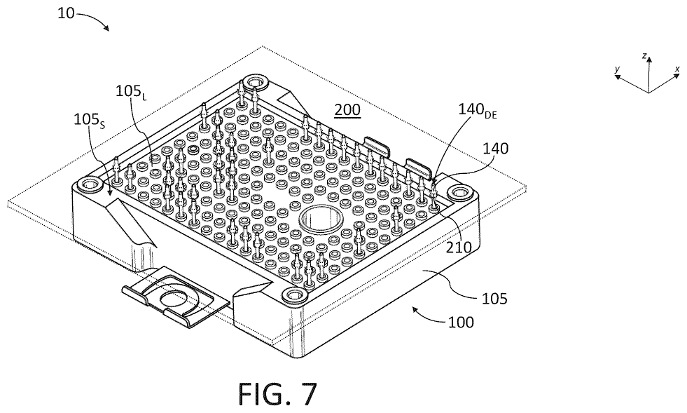

FIG. 7 illustrates an assembly 10 of a power semiconductor module 100 and a component 200, according to an embodiment. The power semiconductor module 100 of FIG. 7 is one example of a power semiconductor module that may be formed using the steps illustrated in and described with reference to FIGS. 1-6B of this disclosure. The power semiconductor module 100 includes a housing 105 that encloses the substrate 110, the power semiconductor die(s) 120, and the sleeves 130. The distal end 140_{DE} of each pin 140 extends beyond a top surface 105_{S} of the housing 105. In this example, the pins 140 extend through openings in a lid 105_{L} of the housing 105, although the housing 105 may also be lidless (i.e., does not include a lid).

The component 200, such as a PCB, includes openings 210 that correspond to the target positions of the pins 140 of the power semiconductor module 100. The power semiconductor module 100 and the component 200 are assembled by inserting the distal end 140_{DE} of each of the pins 140 into a corresponding opening 210 of the component 200. Accurate alignment of the distal end 140_{DE} of the pins 140 may ensure that they can be properly inserted into the openings 210 when assembling the power semiconductor module 100 and the component 200. In some examples, the assembly process can be automated if the pins 140 are sufficiently aligned with the openings 210 within an acceptable tolerance. Thus, forming the power semiconductor module 100 according to the method disclosed herein may ensure sufficiently accurate alignment of the pins 140 relative to their target positions to enable automated assembly of the power semiconductor module 100 and the component 200, potentially providing a more cost-effective manufacturing process.

Although the present disclosure is not so limited, the following numbered examples demonstrate one or more aspects of the disclosure.

Example 1. A method of increasing overall pin alignment accuracy for a power semiconductor module having a plurality of pins, the method comprising: attaching a plurality of sleeves and one or more power semiconductor dies to a first side of a substrate; after the attaching, for each sleeve: measuring a sleeve positional offset between an actual sleeve position and a target sleeve position, and calculating a pin insertion offset based on the sleeve positional offset, wherein the pin insertion offset is measured relative to a reference axis of the sleeve; and for each pin, inserting the pin into a corresponding sleeve, wherein the pin is inserted with the pin insertion offset calculated for the corresponding sleeve, wherein inserting the pin with the pin insertion offset reduces a deviation of a position of the inserted pin from a target position of the inserted pin.

Example 2. The method of example 1, wherein the pin insertion offset includes at least one of a lateral offset and/or an angular offset, wherein the lateral offset and the angular offset are measured relative to the reference axis of the sleeve.

Example 3. The method of example 1 or 2, wherein calculating the pin insertion offset based on the sleeve positional offset comprises inputting the sleeve positional offset into a model.

Example 4. The method of example 3, wherein the model includes one or more of: a geometry of the pins, an elasticity of the pins, a plasticity of the pins, a geometry of the sleeves, an elasticity of the sleeves, and/or a plasticity of the sleeves.

Example 5. The method of any of examples 1 through 4, wherein the position of each inserted pin is a position of a distal end of the inserted pin, and wherein the target position of each inserted pin is a target position of the distal end of the inserted pin.

Example 6. The method of any of examples 1 through 5, wherein measuring the sleeve positional offset between the actual sleeve position and a target sleeve position comprises imaging the plurality of sleeves attached to the substrate.

Example 7. The method of example 6, wherein the imaging comprises x-ray imaging or scanning acoustic microscopy.

Example 8. The method of any of examples 1 through 7, wherein for each pin, inserting the pin into the corresponding sleeve comprises: inserting the pin into the corresponding sleeve with a placement tool.

Example 9. The method of example 8, wherein for each pin, inserting the pin with the pin insertion offset calculated for the corresponding sleeve comprises: before inserting the pin into the corresponding sleeve with the placement tool, adjusting a pin insertion position of the placement tool to account for the pin insertion offset.

Example 10. The method of example 9, wherein for each pin, adjusting the pin insertion position of the placement tool comprises: moving the pin in a lateral direction relative to the reference axis of the sleeve.

Example 11. The method of example 9 or 10, wherein for each pin, adjusting the pin insertion position of the placement tool comprises: tilting the pin at an angle relative to the reference axis of the sleeve.

Example 12. The method of any of examples 9 through 11, wherein for each pin, adjusting the pin insertion position of the placement tool comprises: adjusting the pin insertion position of the placement tool using a piezoelectric actuator.

Example 13. The method of any of examples 8 through 12, wherein for each pin, inserting the pin with the pin insertion offset calculated for the corresponding sleeve comprises: before inserting the pin into the corresponding sleeve with the placement tool, adjusting a pin insertion position of the substrate to account for the pin insertion offset.

Example 14. The method of example 13, wherein for each pin, adjusting the pin insertion position of the substrate comprises: moving the substrate in a lateral direction relative to a pin insertion direction of the pin.

Example 15. The method of example 13 or 14, wherein for each pin, adjusting the pin insertion position of the substrate comprises: tilting the substrate at an angle relative to a pin insertion direction of the pin.

Example 16. The method of any of examples 13 through 15, wherein for each pin, adjusting the pin insertion position of the substrate comprises: adjusting the pin insertion position of the substrate using a piezoelectric actuator.

Example 17. The method of any of examples 1 through 16, wherein a hardness of the pins is greater than a hardness of the sleeves.

Example 18. The method of any of examples 1 through 17, wherein for each sleeve having a non-zero pin insertion offset, a majority of a deformation of the sleeve that occurs when inserting the corresponding pin into the sleeve is plastic deformation.

Example 19. A method for forming a power semiconductor module, the method comprising: attaching a plurality of sleeves and one or more power semiconductor dies to a first side of a substrate; after the attaching, for each sleeve: measuring a sleeve positional offset between an actual sleeve position and a target sleeve position, and calculating a pin insertion offset based on the sleeve positional offset, wherein the pin insertion offset is measured relative to a reference axis of the sleeve; inserting a first pin into a first sleeve having a first pin insertion offset, wherein the first pin is inserted with the first pin insertion offset, and after inserting the first pin into the first sleeve, inserting a second pin into a second sleeve having a second pin insertion offset, wherein the second pin insertion offset is different than the first pin insertion offset, and wherein the second pin is inserted with the second pin insertion offset.

Example 20. The method of example 19, wherein the pin insertion offset includes at least one of a lateral offset and/or an angular offset, wherein the lateral offset and the angular offset are measured relative to the reference axis of the sleeve.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of increasing overall pin alignment accuracy for a power semiconductor module having a plurality of pins, the method comprising:
attaching a plurality of sleeves and one or more power semiconductor dies to a first side of a substrate;
after the attaching, for each sleeve:
measuring a sleeve positional offset between an actual sleeve position and a target sleeve position, and
calculating a pin insertion offset based on the sleeve positional offset, wherein the pin insertion offset is measured relative to a reference axis of the sleeve; and
for each pin, inserting the pin into a corresponding sleeve, wherein the pin is inserted with the pin insertion offset calculated for the corresponding sleeve, wherein inserting the pin with the pin insertion offset reduces a deviation of a position of the inserted pin from a target position of the inserted pin.

2. The method of claim 1, wherein the pin insertion offset includes at least one of a lateral offset and/or an angular offset, wherein the lateral offset and the angular offset are measured relative to the reference axis of the sleeve.

3. The method of claim 1, wherein calculating the pin insertion offset based on the sleeve positional offset comprises inputting the sleeve positional offset into a model.

4. The method of claim 3, wherein the model includes one or more of: a geometry of the pins, an elasticity of the pins, a plasticity of the pins, a geometry of the sleeves, an elasticity of the sleeves, and/or a plasticity of the sleeves.

5. The method of claim 1, wherein the position of each inserted pin is a position of a distal end of the inserted pin, and wherein the target position of each inserted pin is a target position of the distal end of the inserted pin.

6. The method of claim 1, wherein measuring the sleeve positional offset between the actual sleeve position and a target sleeve position comprises imaging the plurality of sleeves attached to the substrate.

7. The method of claim 6, wherein the imaging comprises x-ray imaging or scanning acoustic microscopy.

8. The method of claim 1, wherein for each pin, inserting the pin into the corresponding sleeve comprises:
inserting the pin into the corresponding sleeve with a placement tool.

9. The method of claim 8, wherein for each pin, inserting the pin with the pin insertion offset calculated for the corresponding sleeve comprises:
before inserting the pin into the corresponding sleeve with the placement tool, adjusting a pin insertion position of the placement tool to account for the pin insertion offset.

10. The method of claim 9, wherein for each pin, adjusting the pin insertion position of the placement tool comprises:
moving the pin in a lateral direction relative to the reference axis of the sleeve.

11. The method of claim 9, wherein for each pin, adjusting the pin insertion position of the placement tool comprises:
tilting the pin at an angle relative to the reference axis of the sleeve.

12. The method of claim 9, wherein for each pin, adjusting the pin insertion position of the placement tool comprises:
adjusting the pin insertion position of the placement tool using a piezoelectric actuator.

13. The method of claim 8, wherein for each pin, inserting the pin with the pin insertion offset calculated for the corresponding sleeve comprises:
before inserting the pin into the corresponding sleeve with the placement tool, adjusting a pin insertion position of the substrate to account for the pin insertion offset.

14. The method of claim 13, wherein for each pin, adjusting the pin insertion position of the substrate comprises:
moving the substrate in a lateral direction relative to a pin insertion direction of the pin.

15. The method of claim 13, wherein for each pin, adjusting the pin insertion position of the substrate comprises:
tilting the substrate at an angle relative to a pin insertion direction of the pin.

16. The method of claim 13, wherein for each pin, adjusting the pin insertion position of the substrate comprises:
adjusting the pin insertion position of the substrate using a piezoelectric actuator.

17. The method of claim 1, wherein a hardness of the pins is greater than a hardness of the sleeves.

18. The method of claim 1, wherein for each sleeve having a non-zero pin insertion offset, a majority of a deformation of the sleeve that occurs when inserting the corresponding pin into the sleeve is plastic deformation.

19. A method for forming a power semiconductor module, the method comprising:
attaching a plurality of sleeves and one or more power semiconductor dies to a first side of a substrate;
after the attaching, for each sleeve:
measuring a sleeve positional offset between an actual sleeve position and a target sleeve position, and
calculating a pin insertion offset based on the sleeve positional offset, wherein the pin insertion offset is measured relative to a reference axis of the sleeve;
inserting a first pin into a first sleeve having a first pin insertion offset, wherein the first pin is inserted with the first pin insertion offset, and
after inserting the first pin into the first sleeve, inserting a second pin into a second sleeve having a second pin insertion offset, wherein the second pin insertion offset is different than the first pin insertion offset, and wherein the second pin is inserted with the second pin insertion offset.

20. The method of claim 19, wherein the pin insertion offset includes at least one of a lateral offset and/or an angular offset, wherein the lateral offset and the angular offset are measured relative to the reference axis of the sleeve.
